(19) United States
(12) Patent Application Publication
(10) Pub. No.: US 2026/0350285 A1
(43) Pub. Date: Nov. 5, 2026

(54) ANALOG CIRCUIT ADAPTATION METHOD

(71) Applicant: Apple Inc., Cupertino, CA (US)

(72) Inventors: Siva V. BONASU, Austin, TX (US); Renatas JAKUSHOKAS, Apex, NC (US); William D. SCHWARZ, Austin, TX (US); Yu CHEN, Santa Clara, CA (US)

(21) Appl. No.: 19/198,576

(22) Filed: May 5, 2025

(51) Int. Cl. G06F 30/367

(52) U.S. Cl. CPC G06F 30/367

(57) ABSTRACT

A method for simultaneously adapting an analog circuit for both performance and parametric variation is disclosed. A circuit block that includes multiple adjustable circuit elements is analyzed by a test circuit that measures a figure-of-merit of the circuit block at a series of vectors that correspond to different values for the adjustable circuit elements. At the different vector values, the test circuit determines the figure-of-merit by varying individual ones of the adjustable circuit elements in a neighbor search. The test circuit analyzes the variance in the various figure-of-merit measurements to determine optimized values for the adjustable circuit elements.

### FIELD

This disclosure relates to the field of integrated circuit implementation and, more particularly, to the adaptation of analog circuits.

### BACKGROUND

Modern computer systems include multiple circuit blocks designed to perform various functions. For example, such circuit blocks may include processors or processor cores configured to execute software or program instructions. Additionally, the circuit blocks may include memory circuits, mixed-signal or analog circuits, and the like.

Analog circuit blocks may be used in a variety of applications. For example, some analog circuit blocks are used to convert analog signals into digital data that can be processed by processor or processor core circuits. Additionally, analog circuit blocks may be employed in the interfaces of computer systems to allow such computer systems to receive wired and wireless communication signals.

In addition to transconductance devices, e.g., transistors, analog circuit blocks may also include passive circuit elements. For example, an analog circuit block may include resistors, capacitor, and inductors. In some cases, such passive devices may be adjusted or “trimmed” post-manufacture to achieve desired performance goals for a given analog circuit block.

### BRIEF DESCRIPTION OF THE DRAWINGS

FIG. 1 is a block diagram depicting an embodiment of a circuit test subsystem.

FIG. 2 is a block diagram depicting an embodiment of an adjustable circuit element.

FIG. 3 is a block diagram depicting an embodiment of a vector for adjusting multiple variable circuit elements.

FIG. 4 is a block diagram depicting an embodiment of a Markov Chain Monte Carlo analysis.

FIG. 5 is a block diagram depicting an embodiment of a neighborhood search for a vector.

FIG. 6 is a block diagram of a computer system connected to an external testing device.

FIG. 7 is a block diagram of a computer system that includes two devices coupled to each other via a communication bus.

FIG. 8 is a flow diagram depicting an embodiment of a method for adapting analog circuits.

FIG. 9 is a block diagram of an embodiment of a device that may include analog circuits.

FIG. 10 is a block diagram of various embodiments of computer systems that may include analog circuits.

FIG. 11 illustrates an example of a non-transitory computer-readable storage medium that stores circuit design information.

### DETAILED DESCRIPTION

Computer systems can include a variety of analog circuits. Such analog circuits can be employed as part of power supply voltage and reference voltage generation. Additionally, analog circuits may be used to receive both wired and wireless communication signals.

An analog circuit may include both passive and active circuit elements whose values can vary from instance of the analog circuit to another due to variation in a manufacturing process. To allow some post-manufacture adjustment, analog circuits can sometimes include multiple variable circuit elements such as resistors, capacitors, and the like. Such variable circuit elements can be adjusted to achieve a desired value for figure of merit of a given analog circuit. For example, different resistor and capacitor values can be used to maximize the eye opening for a receiver circuit coupled to a serial data link.

To determine a collection of values for the variable circuit elements that optimize a figure of merit for an analog circuit, a test circuit may check the operation of the analog circuit over random combinations of values for the variable circuit elements. Such an analysis can be performed using a Monte Carlo or other suitable algorithm, and may be performed as part of a final-test operation.

While such an analysis can yield good results, it runs a risk of selecting a set of values for the variable circuit elements that place an analog circuit in a situation where it is highly sensitive to variation in the values of the variable circuit elements. Such a situation can result in poor circuit performance as the values of the variable circuit elements change due to environmental change, e.g., temperature, age, and the like.

The embodiments illustrated in the drawings and described below provide techniques for adapting an analog circuit. By employing a Markov Chain Monte Carlo (MCMC) analysis supplemented with a neighbor search at the different MCMC points, an analog circuit can be optimized for both performance and parametric variation at the same time, thereby improving performance and reliability of the analog circuit.

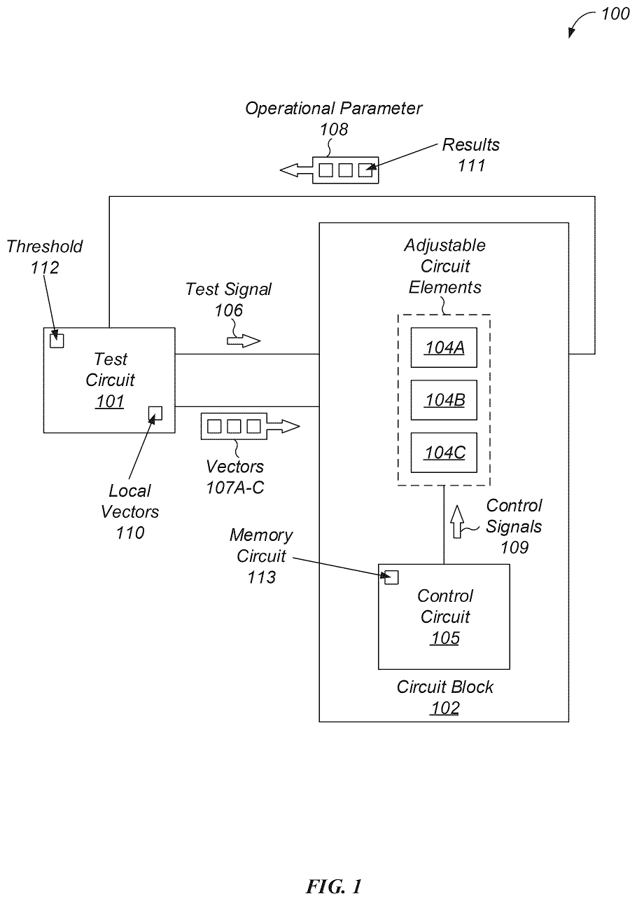

A block diagram of an embodiment of a circuit test subsystem is depicted in FIG. 1. As illustrated, circuit test subsystem 100 includes test circuit 101 and circuit block 102, which includes adjustable circuit elements 104A-104C and control circuit 105. In various embodiments, circuit block 102 may be part of a receiver circuit for a communication channel or link. It is noted that although only three adjustable circuit elements are depicted in the embodiment of FIG. 1, in other embodiments, any suitable number of adjustable circuit elements may be employed.

Test circuit 101 is configured to determine a next vector of vectors 107A-107C using a current value of vectors 107A-107C. A given one of vectors 107A-107C can correspond to a given combination of respective values of adjustable circuit elements 104A-104C. Although only three vectors are depicted in vectors 107A-107C, in other embodiments, any suitable number of vectors may be employed. In some cases, a number of vectors included in vectors 107A-107C may correspond to a number of points in a MCMC analysis.

Test circuit 101 is further configured to measure operational parameter 108 of circuit block 102 using the next vector and local vectors 110 to generate results 111. As described below, local vectors 110 include offsets to individual values included in the next vector. In some cases, a local vector may add or subtract an offset to a given one of the component values in the next vector.

In some embodiments, to measure operational parameter 108, test circuit 101 may generate and transmit test signal 106 to circuit block 102. Test signal 106 may, in some cases, differentially encode multiple test data symbols that can be received and decoded by circuit block 102. In such cases, operational parameter 108 may be based on a characteristic of a data eye associated with test signal 106. In other embodiments, any suitable figure-of-merit related to the operation of circuit block 102 is possible and contemplated.

Test circuit 101 is also configured to determine a variance associated with the next vector value using results 111 for the next vector value, and to perform a comparison of a running variance to threshold 112. In various embodiments, the running variance is based on corresponding variances associated with at least two sequential vector values of vectors 107A-107C. Test circuit 101 is further configured to select a final vector value using a result of the comparison. In some cases, the final vector value may include a particular one of vectors 107A-107C that may include an offset, either positive or negative, associated with one of local vectors 110.

In various embodiments, control circuit 105 may include memory circuit 113 configured to store the final vector value. Control circuit 105 can be configured to generate control signals 109 based on the final vector value. As described below, control signals 109 may be used to operate switches or other suitable devices to modify the values of adjustable circuit elements 104A-104C. In various embodiments, memory circuit 113 may be implemented as a one-time programmable memory circuit, a non-volatile memory circuit, or any other suitable type of memory circuit.

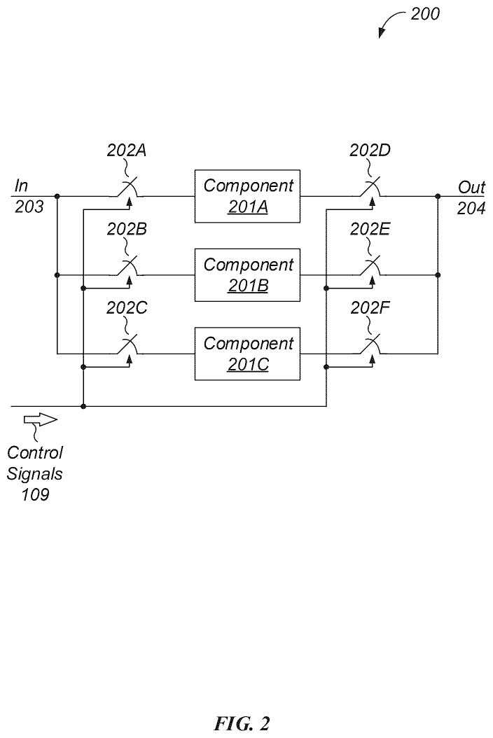

Turning to FIG. 2, a block diagram of an embodiment of an adjustable circuit element is depicted. As illustrated, adjustable circuit element 200 includes components 201A-201C and switches 202A-202F. In various embodiments, adjustable circuit element 200 may correspond to any of adjustable circuit elements 104A-104C as depicted in FIG. 1.

Component 201A is coupled between switch 202A and switch 202D, while component 201B is coupled between switch 202B and switch 202E. In a similar fashion, component 201C is coupled between switch 202C and switch 202F. Although the embodiment of FIG. 2 depicts three components, in other embodiments, adjustable circuit element 200 may include any suitable number of components along with corresponding switches.

Although components 201A-201C are depicted as two-terminal devices, in other embodiments, any of components 201A-201C may have any suitable number of terminals. In various embodiments, components 201A-201C may include resistors, capacitors, inductors, transistors, or any other suitable devices. In different embodiments, each of components 201A-201C may include a common type of component, e.g., a resistor. In such cases, the values of the components included in components 201A-201C may be the same, or they may be different. For example, in some embodiments, the values of components 201A-201C may be binary weighted. As used herein, transistors includes metal-oxide semiconductor field-effect transistors (MOSFETs), Fin field-effect transistors (FinFETs), gate-all-around field-effect transistors (GAAFETs), or any other suitable transconductance devices.

Switches 202A-202F are controlled by control signals 109. By closing pairs of switches, e.g., switches 202A and 202D, different ones of components 201A-201C can be coupled between nodes In 203 and Out 204, thereby changing the resistance, capacitance, inductance, etc., between the two nodes. For example, if switches 202A and 202D are closed, while switches 202B-202F remain open, then component 201A is coupled between nodes In 203 and Out 204. In a similar fashion if switches 202B and 202E are closed, while switches 202A, 202D, 202C, and 202F remain open, then component 201B is coupled between nodes In 203 and Out 204. It is noted that more than one of components 201A-201C can be coupled between nodes In 203 and Out 204.

Switches 202A-202F may be implemented using one or more switching devices, e.g., transistors. For example, switch 202A may be implemented as a single MOSFET. In other cases, switch 202A may be implemented using an n-channel MOSFET in parallel with a p-channel MOSFET. It is noted that a number of signals included in control signals 109 may be based on not only the number of switches included in an adjustable component, but on how the switches are implemented.

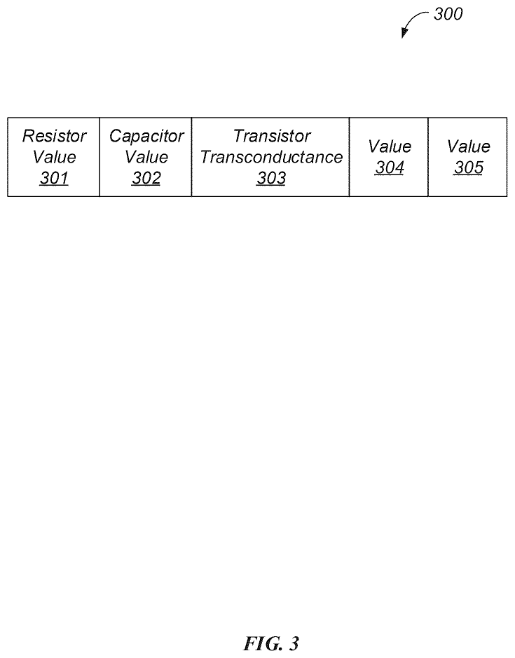

Turning to FIG. 3, a block diagram of an embodiment of a vector for controlling a value of an adjustable component is depicted. As illustrated, vector 300 includes parameters corresponding to resistor value 301, capacitor value 302, transistor transconductance 303, and values 304 and 305. Although five fields are shown in the embodiment of FIG. 3, in other embodiments, any suitable number of fields may be employed. In some embodiments, the number of fields (also referred to as the number of dimensions) of vector 300 may correspond to a number of adjustable components included in a particular circuit block.

Each of resistor value 301, capacitor value 302, transistor transconductance 303, value 304, and value 305 may correspond to numbers of arbitrary units. For example, resistor value 301 may be a value corresponding to a number of components 201A-201C that are coupled between In 203 and Out 204. Alternatively, resistor value 301, capacitor value 302, transistor transconductance 303, value 304, and value 305 may correspond to particular components values. For example, capacitor value 302 may correspond to a number of farads for a capacitor included in adjustable circuit elements 104A-104C as depicted in FIG. 1.

In various embodiments, resistor value 301, capacitor value 302, transistor transconductance 303, value 304, and value 305 may be encoded using a common number of bits. In other embodiments, resistor value 301, capacitor value 302, transistor transconductance 303, value 304, and value 305 may be encoded with respective number of bits. It is noted that the number of bits may be based on an adjustable range of adjustable circuit elements 104A-104C and/or the resolution with which resistor value 301, capacitor value 302, transistor transconductance 303, value 304, and value 305 can be changed.

As described above, multiple vectors, e.g., vectors 107A-107C are used simulate process variation in order to determine the settings for adjustable circuit elements 104A-104C. The values of vectors 107A-107C can be determined using a variety of algorithm. For example, the values of vectors 107A-107C may be determined using a Monte Carlo analysis in which the different values of vectors 107A-107C are determined according to a probability distribution function. This method can generate a large number of values near the center of the probability distribution function. Such values may not exercise circuit block 102 in a sufficient way to optimize performance or account for component variability.

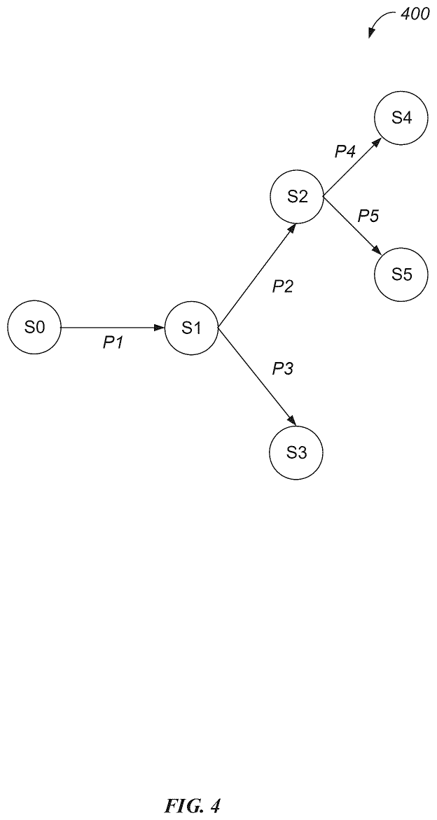

To generate more vectors that place circuit block 102 in regimes of operation that can yield information for optimizing performance, a Markov Chain Monte Carlo analysis can be performed. A diagram depicting an embodiment of a Markov Chain Monte Carlo analysis is illustrated in FIG. 4.

In Markov Chain Monte Carlo analysis 400, the values of adjustable circuit elements 104A-104C are transitioned between states S0 to S5, each of which corresponds to a different vector value, e.g., one of vectors 107A-107C. As described above, at each state, the corresponding vector value is modified using local vectors 110 to perform a neighborhood search.

As part of the Markov Chain Monte Carlo analysis, the particular ones of states S0-S5 that are used in the analysis are determined by probabilities P1-P5. In particular, a selection of the next state of S0-S5 is probabilistically dependent upon the previous state, allowing for a sequence of random variables. For example, if the current state is S1, then the choice of whether the next state is S2 or S3 is dependent on probabilities P2 and P3.

In various embodiments, the Markov Chain Monte Carlo analysis can be performed multiple times, with the results from one pass through the different states (referred to as a “batch”) being used as a starting place for a subsequent pass through the different states.

It is noted that different circuit topologies, different number of adjustable circuit elements, and the like can affect not only a number of possible states, but also the sequence of random values used in the Markov Chain Monte Carlo analysis.

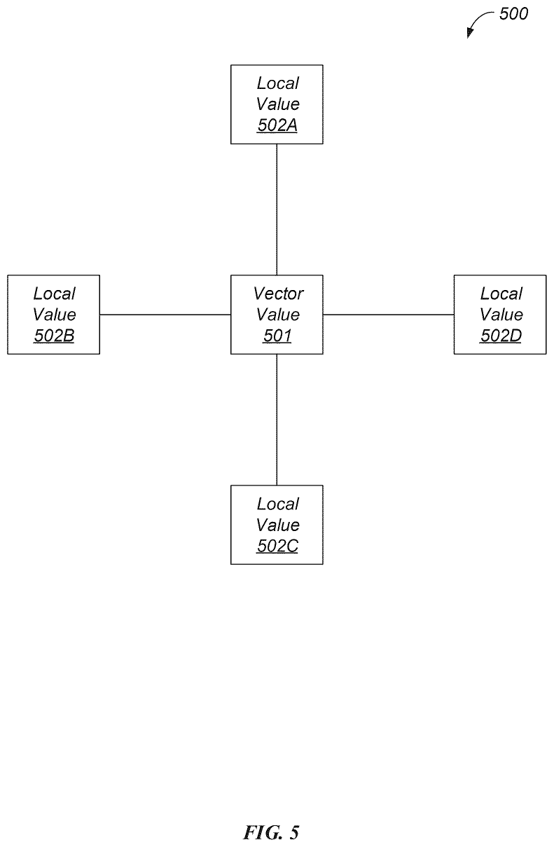

Turning to FIG. 5, a block diagram depicting an embodiment of a neighborhood search for a vector is depicted. As illustrated, neighborhood search 500 includes vector value 501 and local values 502A-502D. Although only four local values are depicted, in other embodiments, any suitable number of local values may be employed. It is noted that test circuit 101 may be configured to perform the operations described in regard to FIG. 5.

Vector value 501 may, in various embodiments, correspond to one of vectors 107A-107C. Local values 502A-502D correspond to vector value 501 with corresponding offsets generated using local vectors 110. A given one of local values 502A-502D may correspond to a change in a particular one of adjustable circuit elements 104A-104C. For example, the value for a given adjustable circuit element may be adjusted by +/−1, +/−2, or any other suitable value. In the cases of adjustments by +/−1, +/−2, the neighborhood search may be referred to as neighborhood search of Manhattan distance 2.

At each of local values 502A-502D, operational parameter 108 is determined and a statistical measurement of the multiple values of operational parameter 108 is generated. The statistical measurement may, in various embodiments, include a mean, a median, a maximum, a minimum, a mode, or any other suitable statistical measurement of the multiple values of operational parameter 108.

The statistical measurement is compared to a threshold value. In various embodiments, for each parameter included in vector value 501, corresponding histogram data is updated based on a parameter's particular value in vector value 501. In some cases, updating the histogram data may include comparing the parameter's particular value in vector value 501 to respective minimum and maximum values for multiple bins that span a range of values for the parameter. In cases, when the statistical measurement is less than the threshold value, the histogram data is not updated.

At the end of each batch, respective variances are determined for the parameters include in a given one of vectors 107A-107C. For example, respective variances are determined for resistor value 301, capacitor value 302, and the like, based on the data gather during a given batch of the Markov Chain Monte Carlo analysis. A variance of the respective variances of the parameters is used to determine a total histogram variance. In various embodiments, a variance of a number of most recent values of the total histogram variance is compared to threshold 112. For example, a variance of the last three total histogram variance values may be compared to threshold 112. Although the example uses the three most recent total histogram variance values, in other embodiments, any suitable number of most recent total histogram variance values may be employed. When the variance of the number of most recent total histogram values is less than threshold 112, the analysis is halted and a final vector value assigned. In some embodiments, a weighted (bin/index count) average of the bins of the histograms associated with the last vector value before the analysis was halted may be used to determine the final vector value.

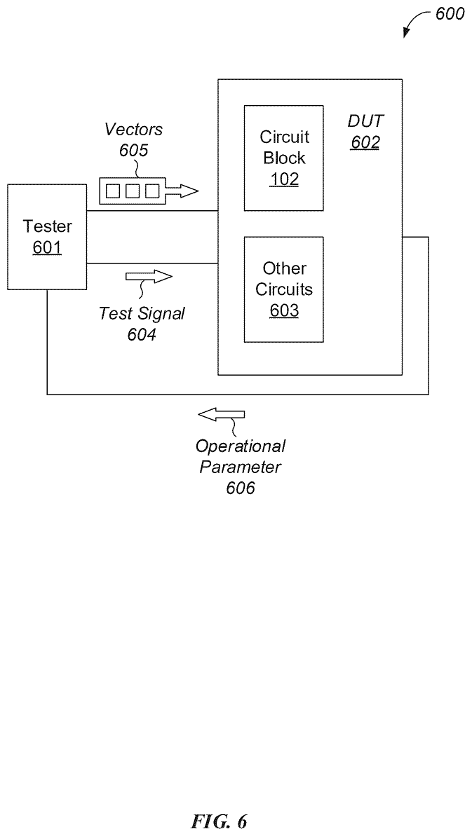

Turning to FIG. 6, a block diagram of an embodiment of a computer system connected to an external testing device is depicted. As illustrated, testing system 600 includes tester 601 and a device-under-test (denoted as “DUT 602”). In various embodiments, DUT 602 may be an integrated circuit on a wafer, a package integrated circuit, a system-on-a-chip, or any other suitable device to be tested.

DUT 602 includes circuit block 102 and other circuits 603. In various embodiments, circuit block 102 may correspond to a SERDES receiver circuit or any other suitable circuit that includes analog components. Other circuits 603 may include memory circuits, processor circuits, mixed-signal/analog circuits, or any other suitable circuits.

Tester 601 may be a standalone tester configured to test multiple integrated circuits as part of a post-manufacture test procedure. In some embodiments, tester 601 is configured to transmit vectors 605 and test signal 604 to DUT 602. In various embodiments, vectors 605 may correspond to vectors 107A-C as depicted in FIG. 1, and may be used to modify the values of adjustable circuit elements 104A-104C. Additionally, test signal 604 may correspond to test signal 106 generated by test circuit 101.

In various embodiments, tester 601 may be configured to receive operational parameter 606 from DUT 602, and perform functions and/or operations similar to those of test circuit 101 as depicted in FIG. 1. In some cases, operational parameter 606 may be a direct measurement of a parameter, e.g., power supply voltage level, or DUT 602. In other cases, operational parameter 606 may be a digital signal including multiple bits that encode information about the parameter that can be measured by circuit block 102 or other circuits 603.

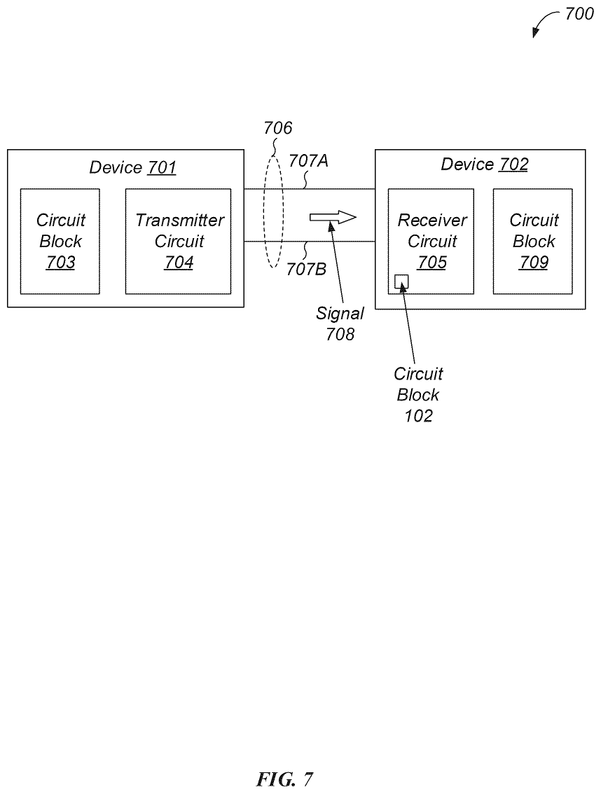

As described above, a circuit block that includes adjustable circuit elements may be part of a receiver circuit for receiving and processing data from a communication channel or link. A block diagram of an embodiment of a computer system that includes two devices coupled to each other via a communication bus is depicted in FIG. 7. As illustrated, computer system 700 includes devices 701 and 702 coupled by communication bus 706.

Device 701 includes circuit block 703 and transmitter circuit 704. In various embodiments, device 701 may be a processor circuit, a processor core, a memory circuit, or any other suitable circuit block that may be included on an integrated circuit in a computer system. It is noted that although device 701 only depicts a single circuit block and a single transmitter circuit, in other embodiments, additional circuit blocks and additional transmitter circuits may be employed.

Transmitter circuit 704 is configured to serially transmit signal 708, via communication bus 706, corresponding to data received from circuit block 703. Such signals may differentially encode one or more bits or symbols such that a difference between the respective voltage levels of wires 707A and 707B, at a particular point in time, correspond to a particular bit or symbol value. In some cases, the generation of signal 708 may include encoding the bits prior to transmission. It is noted that although communication bus 706 is depicted as including two wires, in other embodiments, any suitable number of wires may be employed.

Device 702 includes receiver circuit 705 and circuit block 709. Like device 701, device 702 may be a processor circuit, a processor core, a memory circuit, or any other suitable circuit block configured to receive data from transmitter circuit 704. In various embodiments, receiver circuit 705 may include circuit block 102 with adjustable circuit elements 104A-104C as depicted in FIG. 1.

Devices 701 and 702 may, in some embodiments, be fabricated on a common integrated circuit. In other embodiments, devices 701 and 702 may be located on different integrated circuits mounted on a common substrate or circuit board. In such cases, communication bus 706 may include metal or other conductive traces on the substrate or circuit boards. Although only two devices are depicted in computer system 700, in other embodiments, any suitable number of devices may be employed.

To summarize, various embodiments of a technique for adapting analog circuits are disclosed. Broadly speaking, a circuit block can include a plurality of adjustable circuit components. A test circuit may be configured to determine a next vector value of a plurality of vector values using a current vector value of the plurality of vector values, where a given vector value corresponds to a given combination of respective values of the plurality of adjustable circuit components. The test circuit may be further configured to measure an operational parameter of the circuit block using the next vector value and a plurality of local vector values associated with the next vector value to generate a plurality of results, where the plurality of local vector values includes a given local vector value that includes the next vector value plus an offset for one value of the plurality of adjustable circuit components. Additionally, the test may determine a variance associated with the next vector value using the plurality of results for the next vector value, and perform a comparison of a running variance to a threshold value, where the running variance is based on corresponding variances associated with at least two sequential vector values of the plurality of vector values. The test circuit may also be configured to select a final vector value of the plurality of vector values using a result of the comparison.

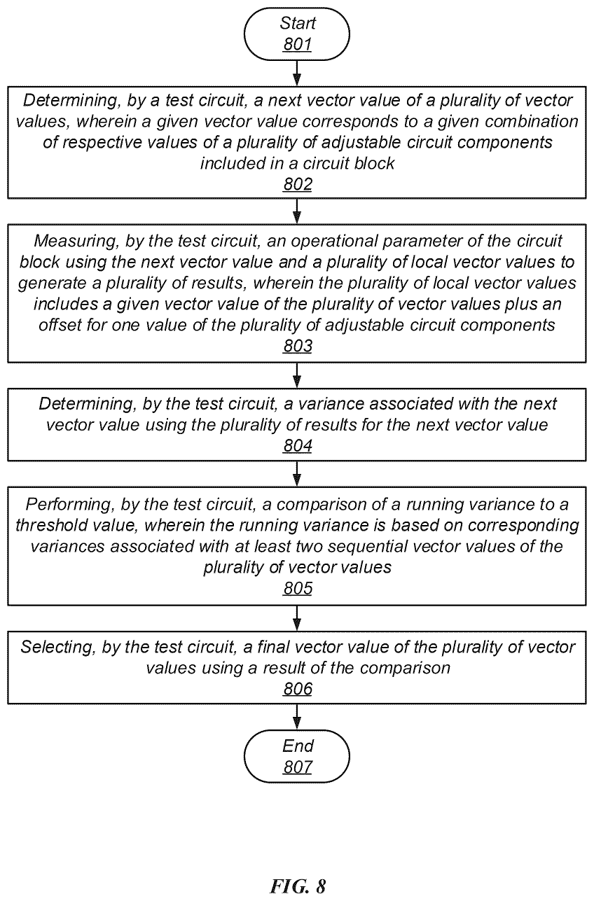

Turning to FIG. 8, a flow diagram depicting an embodiment of a method for adapting an analog circuit is illustrated. The method, which may be applied to various analog circuits, e.g., circuit block 102 as depicted in FIG. 1, begins in block 801.

The method includes determining, by a test circuit, a next vector value of a plurality of vector values (block 802). In various embodiments, a given vector value of the plurality of vector values corresponds to a given combination of respective values of a plurality of adjustable circuit components included in a circuit block. In various embodiments, the plurality of adjustable circuit components may include any suitable combination of resistors, capacitors, inductors, transistors, and the like.

In some embodiments, determining the next vector value may be based on respective probabilities of a subset of the plurality of vector values to which a current vector value may transition. For example, in some cases, determining the next vector value may be determined according to a Markov Chain Monte Carlo algorithm.

The method also includes measuring, by the test circuit, an operational parameter of the circuit block using the next vector value and a plurality of local vector values to generate a plurality of results (block 803). In various embodiments, the plurality of local vector values includes a given vector value of the plurality of vector values plus an offset for one value of the plurality of adjustable circuit components. In some embodiments, a particular local vector value that corresponds to a minimum value of the measured operational parameter may be assigned to the next vector value.

In some embodiments, the test circuit and the circuit block may be located on a common integrated circuit. In other cases, the test circuit may be implemented as a standalone tester that is configured to test multiple circuit blocks on a common integrated circuit, or on different integrated circuits on a wafer during a post-manufacture final test.

The method further includes determining, by the test circuit, a variance associated with the next vector value using the plurality of results for the next vector value (block 804). In various embodiments, determining the variance includes determining respective variances of histograms of respective measured operational parameter results for the plurality of local vector values centered at each of the plurality of vector values.

The method also includes performing, by the test circuit, a comparison of a running variance to a threshold value (block 805). In various embodiments, the running variance is based on corresponding variances associated with at least two sequential vector values of the plurality of vector values. In some cases, the running variance may correspond to a variance of the respective histogram variances of the last three vector values of the plurality of vector values.

The method further includes selecting, by the test circuit, a final vector value of the plurality of vector values using a result of the comparison (block 806). In some embodiments, the method also include storing, by the circuit block, the final vector value. The final vector value may, in different embodiments, be stored in a non-volatile memory circuit, a one-time programmable memory circuit, or any other suitable memory circuit. During mission mode, i.e., non-test mode operation, the final vector value determines the respective values for the plurality of adjustable components. The method concludes in block 807.

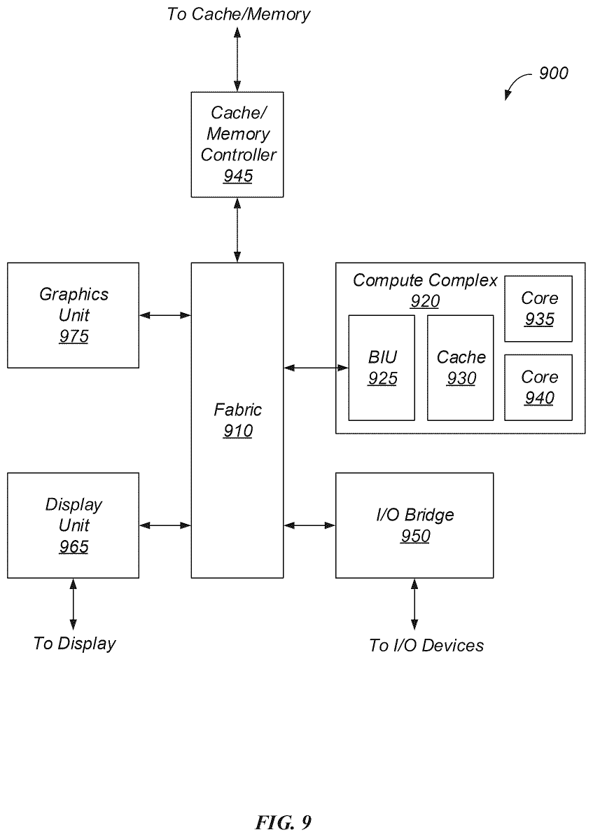

Referring now to FIG. 9, a block diagram illustrating an example embodiment of a device is shown. In some embodiments, elements of device 900 may be included within a system-on-a-chip. In some embodiments, device 900 may be included in a mobile device, which may be battery-powered. Therefore, power consumption by device 900 may be an important design consideration. In the illustrated embodiment, device 900 includes fabric 910, compute complex 920, input/output (I/O) bridge 950, cache/memory controller 945, graphics unit 975, and display unit 965. In some embodiments, device 900 may include other components (not shown) in addition to, or in place of, the illustrated components, such as video processor encoders and decoders, image processing or recognition elements, computer vision elements, etc.

Fabric 910 may include various interconnects, buses, MUX's, controllers, etc., and may be configured to facilitate communication between various elements of device 900. In some embodiments, portions of fabric 910 may be configured to implement various different communication protocols. In other embodiments, fabric 910 may implement a single communication protocol, and elements coupled to fabric 910 may convert from the single communication protocol to other communication protocols internally.

In the illustrated embodiment, compute complex 920 includes bus interface unit (BIU) 925, cache 930, and cores 935 and 940. In various embodiments, compute complex 920 may include various numbers of processors, processor cores, and caches. For example, compute complex 920 may include 1, 2, or 4 processor cores, or any other suitable number. In one embodiment, cache 930 is a set associative L2 cache. In some embodiments, cores 935 and 940 may include internal instruction and data caches. In some embodiments, a coherency unit (not shown) in fabric 910, cache 930, or elsewhere in device 900, may be configured to maintain coherency between various caches of device 900. BIU 925 may be configured to manage communication between compute complex 920 and other elements of device 900. Processor cores, such as cores 935 and 940, may be configured to execute instructions of a particular instruction set architecture (ISA) which may include operating system instructions and user application instructions. These instructions may be stored in a computer readable medium such as a memory coupled to cache/memory controller 945 as discussed below.

As used herein, the term “coupled to” may indicate one or more connections between elements, and a coupling may include intervening elements. For example, in FIG. 9, graphics unit 975 may be described as “coupled to” a memory through fabric 910 and cache/memory controller 945. In contrast, in the illustrated embodiment of FIG. 9, graphics unit 975 is “directly coupled” to fabric 910 because there are no intervening elements.

Cache/memory controller 945 may be configured to manage transfer of data between fabric 910 and one or more caches and memories. For example, cache/memory controller 945 may be coupled to an L3 cache, which may, in turn, be coupled to a system memory. In other embodiments, cache/memory controller 945 may be directly coupled to a memory. In some embodiments, cache/memory controller 945 may include one or more internal caches. Memory coupled to cache/memory controller 945 may be any type of volatile memory, such as dynamic random access memory (DRAM), synchronous DRAM (SDRAM), double data rate (DDR, DDR2, DDR3, etc.) SDRAM (including mobile versions of SDRAMs such as mDDR3, etc., and/or low power versions of SDRAMs such as LPDDR4, etc.), RAMBUS DRAM (RDRAM), static RAM (SRAM), etc. One or more memory devices may be coupled onto a circuit board to form memory modules such as single inline memory modules (SIMMs), dual inline memory modules (DIMMs), etc. Alternatively, the devices may be mounted with an integrated circuit in a chip-on-chip configuration, a package-on-package configuration, or a multi-chip module configuration. Memory coupled to cache/memory controller 945 may be any type of non-volatile memory such as NAND flash memory, NOR flash memory, nano RAM (NRAM), magneto-resistive RAM (MRAM), phase change RAM (PRAM), Racetrack memory, Memristor memory, etc. As noted above, this memory may store program instructions executable by compute complex 920 to cause the computing device to perform functionality described herein.

Graphics unit 975 may include one or more processors, e.g., one or more graphics processing units (GPUs). Graphics unit 975 may receive graphics-oriented instructions, such as OPENGL®, Metal®, or DIRECT3D® instructions, for example. Graphics unit 975 may execute specialized GPU instructions or perform other operations based on the received graphics-oriented instructions. Graphics unit 975 may generally be configured to process large blocks of data in parallel, and may build images in a frame buffer for output to a display, which may be included in the device or may be a separate device. Graphics unit 975 may include transform, lighting, triangle, and rendering engines in one or more graphics processing pipelines. Graphics unit 975 may output pixel information for display images. Graphics unit 975, in various embodiments, may include programmable shader circuitry which may include highly parallel execution cores configured to execute graphics programs, which may include pixel tasks, vertex tasks, and compute tasks (which may or may not be graphics-related).

Display unit 965 may be configured to read data from a frame buffer and provide a stream of pixel values for display. Display unit 965 may be configured as a display pipeline in some embodiments. Additionally, display unit 965 may be configured to blend multiple frames to produce an output frame. Further, display unit 965 may include one or more interfaces (e.g., MIPI® or embedded display port (eDP)) for coupling to a user display (e.g., a touchscreen or an external display).

I/O bridge 950 may include various elements configured to implement universal serial bus (USB) communications, security, audio, and low-power always-on functionality, for example. I/O bridge 950 may also include interfaces such as pulse-width modulation (PWM), general-purpose input/output (GPIO), serial peripheral interface (SPI), and inter-integrated circuit (I2C), for example. Various types of peripherals and devices may be coupled to device 900 via I/O bridge 950.

In some embodiments, device 900 includes network interface circuitry (not explicitly shown), which may be connected to fabric 910 or I/O bridge 950. The network interface circuitry may be configured to communicate via various networks, which may be wired, wireless, or both. For example, the network interface circuitry may be configured to communicate via a wired local area network, a wireless local area network (e.g., via Wi-Fi™), or a wide area network (e.g., the Internet or a virtual private network). In some embodiments, the network interface circuitry is configured to communicate via one or more cellular networks that use one or more radio access technologies. In some embodiments, the network interface circuitry is configured to communicate using device-to-device communications (e.g., Bluetooth® or Wi-Fi™ Direct), etc. In various embodiments, the network interface circuitry may provide device 900 with connectivity to various types of other devices and networks.

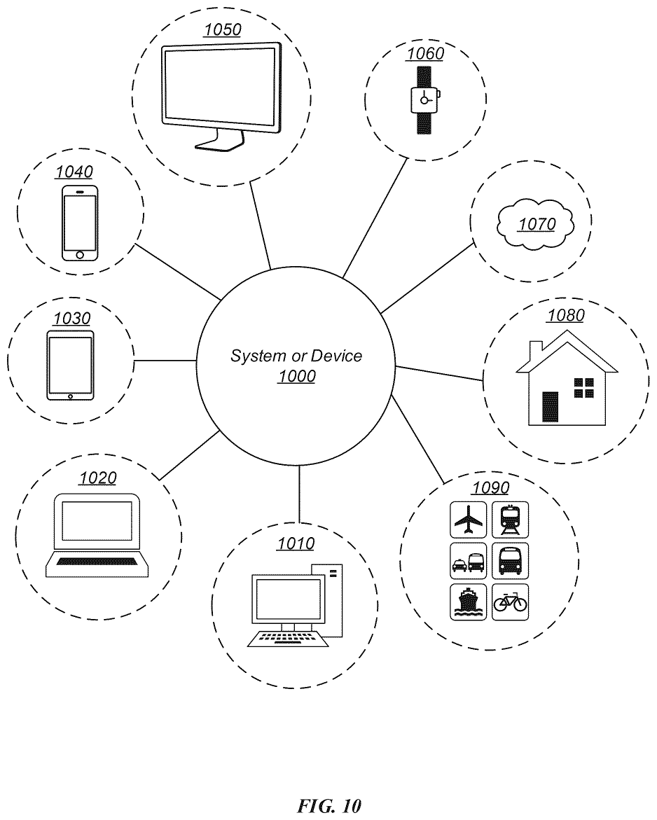

Turning now to FIG. 10, various types of systems that may include any of the circuits, devices, or systems discussed above are illustrated. System or device 1000, which may incorporate or otherwise utilize one or more of the techniques described herein, may be utilized in a wide range of areas. For example, system or device 1000 may be utilized as part of the hardware of systems such as a desktop computer 1010, laptop computer 1020, tablet computer 1030, cellular or mobile phone 1040, or television 1050 (or set-top box coupled to a television).

Similarly, disclosed elements may be utilized in a wearable device 1060, such as a smartwatch or a health-monitoring device. Smartwatches, in many embodiments, may implement a variety of different functions—for example, access to email, cellular service, calendar, health monitoring, etc. A wearable device may also be designed solely to perform health-monitoring functions, such as monitoring a user's vital signs, performing epidemiological functions such as contact tracing, providing communication to an emergency medical service, etc. Other types of devices are also contemplated, including devices worn on the neck, devices implantable in the human body, glasses or a helmet designed to provide computer-generated reality experiences such as those based on augmented and/or virtual reality, etc.

System or device 1000 may also be used in various other contexts. For example, system or device 1000 may be utilized in the context of a server computer system, such as a dedicated server or on shared hardware that implements a cloud-based service 1070. Still further, system or device 1000 may be implemented in a wide range of specialized everyday devices, including devices 1080 commonly found in the home such as refrigerators, thermostats, security cameras, etc. The interconnection of such devices is often referred to as the “Internet of Things” (IoT). Elements may also be implemented in various modes of transportation. For example, system or device 1000 could be employed in the control systems, guidance systems, entertainment systems, etc. of various types of vehicles 1090.

The applications illustrated in FIG. 10 are merely exemplary and are not intended to limit the potential future applications of disclosed systems or devices. Other example applications include, without limitation: portable gaming devices, music players, data storage devices, unmanned aerial vehicles, etc.

The present disclosure has described various example circuits in detail above. It is intended that the present disclosure cover not only embodiments that include such circuitry, but also a computer-readable storage medium that includes design information that specifies such circuitry. Accordingly, the present disclosure is intended to support claims that cover not only an apparatus that includes the disclosed circuitry, but also a storage medium that specifies the circuitry in a format that programs a computing system to generate a simulation model of the hardware circuit, programs a fabrication system configured to produce hardware (e.g., an integrated circuit) that includes the disclosed circuitry, etc. Claims to such a storage medium are intended to cover, for example, an entity that produces a circuit design, but does not itself perform complete operations such as design simulation, design synthesis, circuit fabrication, etc.

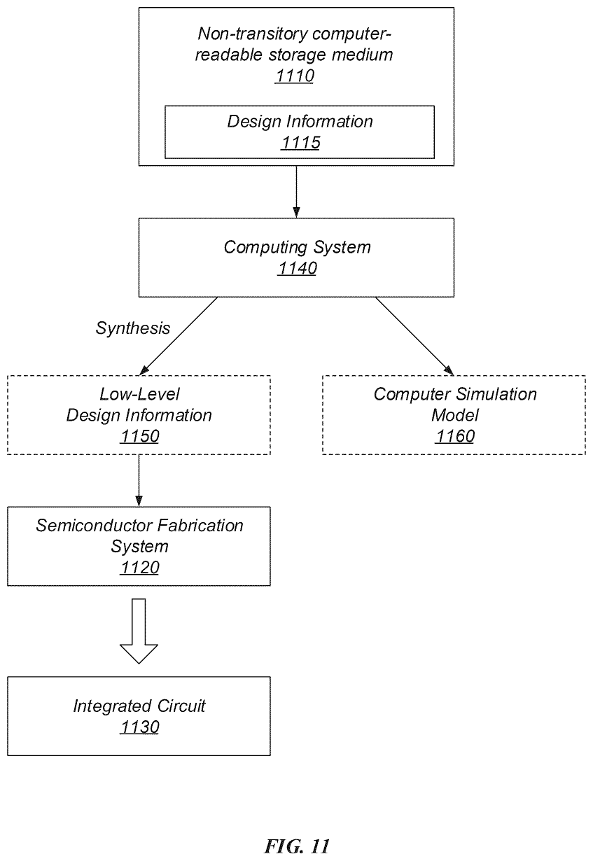

FIG. 11 is a block diagram illustrating an example of a non-transitory computer-readable storage medium that stores design information 1115, according to some embodiments. In the illustrated embodiment, computing system 1140 is configured to process design information 1115. This may include executing instructions included in design information 1115, interpreting instructions included in design information 1115, compiling, transforming, or otherwise updating design information 1115, etc. Therefore, design information 1115 controls computing system 1140 (e.g., by programming computing system 1140) to perform various operations discussed below, in some embodiments.

In the illustrated example, computing system 1140 processes design information 1115 to generate both computer simulation model of hardware circuit 1160 and low-level design information 1150. In other embodiments, computing system 1140 may generate only one of these outputs, may generate other outputs based on design information 1115, or both. Regarding computer simulation model of hardware circuit 1160, computing system 1140 may execute instructions of a hardware description language that includes register transfer level (RTL) code, behavioral code, structural code, or some combination thereof. The simulation model may perform the functionality specified by design information 1115, facilitate verification of the functional correctness of the hardware design, generate power consumption estimates, generate timing estimates, etc.

In the illustrated example, computing system 1140 also processes design information 1115 to generate low-level design information 1150 (e.g., gate-level design information, a netlist, etc.). This may include synthesis operations, as shown, such as constructing a multi-level network, optimizing the network using technology-independent techniques, technology dependent techniques, or both, and outputting a network of gates (with potential constraints based on available gates in a technology library, sizing, delay, power, etc.). Based on low-level design information 1150 (potentially among other inputs), semiconductor fabrication system 1120 is configured to fabricate integrated circuit 1130 (which may correspond to functionality of the computer simulation model of hardware circuit 1160). Note that computing system 1140 may generate different simulation models based on design information at various levels of description, including low-level design information 1150, design information 1115, and so on. The data representing low-level design information 1150 and computer simulation model of hardware circuit 1160 may be stored on non-transitory computer-readable storage medium 1110, or on one or more other media.

In some embodiments, low-level design information 1150 controls (e.g., programs) semiconductor fabrication system 1120 to fabricate integrated circuit 1130. Thus, when processed by the fabrication system, the design information may program the fabrication system to fabricate a circuit that includes various circuitry disclosed herein.

Non-transitory computer-readable storage medium 1110 may comprise any of various appropriate types of memory devices or storage devices. Non-transitory computer-readable storage medium 1110 may be an installation medium, e.g., a CD-ROM, floppy disks, or tape device; a computer system memory or random access memory such as DRAM, DDR RAM, SRAM, EDO RAM, Rambus RAM, etc. ; a non-volatile memory such as a Flash memory, magnetic media, e.g., a hard drive, or optical storage; registers, or other similar types of memory elements, etc. Non-transitory computer-readable storage medium 1110 may include other types of non-transitory memory as well, or combinations thereof. Accordingly, non-transitory computer-readable storage medium 1110 may include two or more memory media, which may reside in different locations—for example, in different computer systems that are connected over a network.

Design information 1115 may be specified using any of various appropriate computer languages, including hardware description languages such as, without limitation: VHDL, Verilog, SystemC, SystemVerilog, RHDL, M, MyHDL, etc. The format of various design information may be recognized by one or more applications executed by computing system 1140, semiconductor fabrication system 1120, or both. In some embodiments, design information 1115 may also include one or more cell libraries that specify the synthesis, layout, or both of integrated circuit 1130. In some embodiments, design information 1115 is specified in whole, or in part, in the form of a netlist that specifies cell library elements and their connectivity. Design information discussed herein, taken alone, may or may not include sufficient information for fabrication of a corresponding integrated circuit. For example, design information may specify the circuit elements to be fabricated but not their physical layout. In this case, design information may be combined with layout information to actually fabricate the specified circuitry.

Integrated circuit 1130 may, in various embodiments, include one or more custom macrocells, such as memories, analog or mixed-signal circuits, and the like. In such cases, design information 1115 may include information related to included macrocells. Such information may include, without limitation, schematics capture database, mask design data, behavioral models, and device or transistor level netlists. Mask design data may be formatted according to graphic data system (GDSII), or any other suitable format.

Semiconductor fabrication system 1120 may include any of various appropriate elements configured to fabricate integrated circuits. This may include, for example, elements for depositing semiconductor materials (e.g., on a wafer, which may include masking), removing materials, altering the shape of deposited materials, modifying materials (e.g., by doping materials or modifying dielectric constants using ultraviolet processing), etc. Semiconductor fabrication system 1120 may also be configured to perform various testing of fabricated circuits for correct operation.

In various embodiments, integrated circuit 1130 and computer simulation model of hardware circuit 1160 are configured to operate according to a circuit design specified by design information 1115, which may include performing any of the functionality described herein. For example, integrated circuit 1130 may include any of various elements shown in FIGS. 1-3. Further, integrated circuit 1130 may be configured to perform various functions described herein in conjunction with other components. Further, the functionality described herein may be performed by multiple connected integrated circuits.

As used herein, a phrase of the form “design information that specifies a design of a circuit configured to . . . ” does not imply that the circuit in question must be fabricated in order for the element to be met. Rather, this phrase indicates that the design information describes a circuit that, upon being fabricated, will be configured to perform the indicated actions or will include the specified components. Similarly, stating “instructions of a hardware description programming language” that are “executable” to program a computing system to generate a computer simulation model does not imply that the instructions must be executed in order for the element to be met, but rather, specifies characteristics of the instructions. Additional features relating to the model (or the circuit represented by the model) may similarly relate to characteristics of the instructions, in this context. Therefore, an entity that sells a computer-readable medium with instructions that satisfy recited characteristics may provide an infringing product, even if another entity actually executes the instructions on the medium.

Note that a given design, at least in the digital logic context, may be implemented using a multitude of different gate arrangements, circuit technologies, etc. As one example, different designs may select or connect gates based on design tradeoffs (e.g., to focus on power consumption, performance, circuit area, etc.). Further, different manufacturers may have proprietary libraries, gate designs, physical gate implementations, etc. Different entities may also use different tools to process design information at various layers (e.g., from behavioral specifications to physical layout of gates).

Once a digital logic design is specified, however, those skilled in the art need not perform substantial experimentation or research to determine those implementations. Rather, those of skill in the art understand procedures to reliably and predictably produce one or more circuit implementations that provide the function described by design information 1115. The different circuit implementations may affect the performance, area, power consumption, etc. of a given design (potentially with tradeoffs between different design goals), but the logical function does not vary among the different circuit implementations of the same circuit design.

In some embodiments, the instructions included in design information 1115 provide RTL information (or other higher-level design information) and are executable by the computing system to synthesize a gate-level netlist that represents the hardware circuit based on the RTL information as an input. Similarly, the instructions may provide behavioral information and be executable by the computing system to synthesize a netlist or other lower-level design information included in low-level design information 1150. Low-level design information 1150 may program semiconductor fabrication system 1120 to fabricate integrated circuit 1130.

The present disclosure includes references to an “embodiment” or groups of “embodiments” (e.g., “some embodiments” or “various embodiments”). Embodiments are different implementations or instances of the disclosed concepts. References to “an embodiment,” “one embodiment,” “a particular embodiment,” and the like do not necessarily refer to the same embodiment. A large number of possible embodiments are contemplated, including those specifically disclosed, as well as modifications or alternatives that fall within the spirit or scope of the disclosure.

This disclosure may discuss potential advantages that may arise from the disclosed embodiments. Not all implementations of these embodiments will necessarily manifest any or all of the potential advantages. Whether an advantage is realized for a particular implementation depends on many factors, some of which are outside the scope of this disclosure. In fact, there are a number of reasons why an implementation that falls within the scope of the claims might not exhibit some or all of any disclosed advantages. For example, a particular implementation might include other circuitry outside the scope of the disclosure that, in conjunction with one of the disclosed embodiments, negates or diminishes one or more of the disclosed advantages. Furthermore, suboptimal design execution of a particular implementation (e.g., implementation techniques or tools) could also negate or diminish disclosed advantages. Even assuming a skilled implementation, realization of advantages may still depend upon other factors such as the environmental circumstances in which the implementation is deployed. For example, inputs supplied to a particular implementation may prevent one or more problems addressed in this disclosure from arising on a particular occasion, with the result that the benefit of its solution may not be realized. Given the existence of possible factors external to this disclosure, it is expressly intended that any potential advantages described herein are not to be construed as claim limitations that must be met to demonstrate infringement. Rather, identification of such potential advantages is intended to illustrate the type(s) of improvement available to designers having the benefit of this disclosure. That such advantages are described permissively (e.g., stating that a particular advantage “may arise”) is not intended to convey doubt about whether such advantages can in fact be realized, but rather to recognize the technical reality that realization of such advantages often depends on additional factors.

Unless stated otherwise, embodiments are non-limiting. That is, the disclosed embodiments are not intended to limit the scope of claims that are drafted based on this disclosure, even where only a single example is described with respect to a particular feature. The disclosed embodiments are intended to be illustrative rather than restrictive, absent any statements in the disclosure to the contrary. The application is thus intended to permit claims covering disclosed embodiments, as well as such alternatives, modifications, and equivalents that would be apparent to a person skilled in the art having the benefit of this disclosure.

For example, features in this application may be combined in any suitable manner. Accordingly, new claims may be formulated during prosecution of this application (or an application claiming priority thereto) to any such combination of features. In particular, with reference to the appended claims, features from dependent claims may be combined with those of other dependent claims where appropriate, including claims that depend from other independent claims. Similarly, features from respective independent claims may be combined where appropriate.

Accordingly, while the appended dependent claims may be drafted such that each depends on a single other claim, additional dependencies are also contemplated. Any combinations of features in the dependent claims that are consistent with this disclosure are contemplated and may be claimed in this or another application. In short, combinations are not limited to those specifically enumerated in the appended claims.

Where appropriate, it is also contemplated that claims drafted in one format or statutory type (e.g., apparatus) are intended to support corresponding claims of another format or statutory type (e.g., method).

Because this disclosure is a legal document, various terms and phrases may be subject to administrative and judicial interpretation. Public notice is hereby given that the following paragraphs, as well as definitions provided throughout the disclosure, are to be used in determining how to interpret claims that are drafted based on this disclosure.

References to a singular form of an item (i.e., a noun or noun phrase preceded by “a,” “an,” or “the”) are, unless context clearly dictates otherwise, intended to mean “one or more.” Reference to “an item” in a claim thus does not, without accompanying context, preclude additional instances of the item. A “plurality” of items refers to a set of two or more of the items.

The word “may” is used herein in a permissive sense (i.e., having the potential to, being able to) and not in a mandatory sense (i.e., must).

The terms “comprising” and “including,” and forms thereof, are open-ended and mean “including, but not limited to.”

When the term “or” is used in this disclosure with respect to a list of options, it will generally be understood to be used in the inclusive sense unless the context provides otherwise. Thus, a recitation of “x or y” is equivalent to “x or y, or both,” and thus covers 1) x but not y, 2) y but not x, and 3) both x and y. On the other hand, a phrase such as “either x or y, but not both” makes clear that “or” is being used in the exclusive sense.

A recitation of “w, x, y, or z, or any combination thereof” or “at least one of . . . w, x, y, and z” is intended to cover all possibilities involving a single element up to the total number of elements in the set. For example, given the set [w, x, y, z], these phrasings cover any single element of the set (e.g., w but not x, y, or z), any two elements (e.g., w and x, but not y or z), any three elements (e.g., w, x, and y, but not z), and all four elements. The phrase “at least one of . . . w, x, y, and z” thus refers to at least one element of the set [w, x, y, z], thereby covering all possible combinations in this list of elements. This phrase is not to be interpreted to require that there is at least one instance of w, at least one instance of x, at least one instance of y, and at least one instance of z.

Various “labels” may precede nouns or noun phrases in this disclosure. Unless context provides otherwise, different labels used for a feature (e.g., “first circuit,” “second circuit,” “particular circuit,” “given circuit,” etc.) refer to different instances of the feature. Additionally, the labels “first,” “second,” and “third,” when applied to a feature, do not imply any type of ordering (e.g., spatial, temporal, logical, etc.), unless stated otherwise.

The phrase “based on” is used to describe one or more factors that affect a determination. This term does not foreclose the possibility that additional factors may affect the determination. That is, a determination may be solely based on specified factors, or based on the specified factors as well as other, unspecified factors. Consider the phrase “determine A based on B.” This phrase specifies that B is a factor that is used to determine A or that affects the determination of A. This phrase does not foreclose that the determination of A may also be based on some other factor, such as C. This phrase is also intended to cover an embodiment in which A is determined based solely on B. As used herein, the phrase “based on” is synonymous with the phrase “based at least in part on.”

The phrases “in response to” and “responsive to” describe one or more factors that trigger an effect. This phrase does not foreclose the possibility that additional factors may affect or otherwise trigger the effect, either jointly with the specified factors or independent from the specified factors. That is, an effect may be solely in response to those factors, or may be in response to the specified factors as well as other, unspecified factors. Consider the phrase “perform A in response to B.” This phrase specifies that B is a factor that triggers the performance of A, or that triggers a particular result for A. This phrase does not foreclose that performing A may also be in response to some other factor, such as C. This phrase also does not foreclose that performing A may be jointly in response to B and C. This phrase is also intended to cover an embodiment in which A is performed solely in response to B. As used herein, the phrase “responsive to” is synonymous with the phrase “responsive at least in part to.” Similarly, the phrase “in response to” is synonymous with the phrase “at least in part in response to.”

Within this disclosure, different entities (which may variously be referred to as “units,” “circuits,” other components, etc.) may be described or claimed as “configured” to perform one or more tasks or operations. This formulation—[entity] configured to [perform one or more tasks]—is used herein to refer to structure (i.e., something physical). More specifically, this formulation is used to indicate that this structure is arranged to perform the one or more tasks during operation. A structure can be said to be “configured to” perform some task even if the structure is not currently being operated. Thus, an entity described or recited as being “configured to” perform some task refers to something physical, such as a device, a circuit, or a system having a processor unit and a memory storing program instructions executable to implement the task, etc. This phrase is not used herein to refer to something intangible.

In some cases, various units/circuits/components may be described herein as performing a set of tasks or operations. It is understood that those entities are “configured to” perform those tasks/operations, even if not specifically noted.

The term “configured to” is not intended to mean “configurable to.” An unprogrammed FPGA, for example, would not be considered to be “configured to” perform a particular function. This unprogrammed FPGA may be “configurable to” perform that function, however. After appropriate programming, the FPGA may then be said to be “configured to” perform the particular function.

For purposes of United States patent applications based on this disclosure, reciting in a claim that a structure is “configured to” perform one or more tasks is expressly intended not to invoke 35 U.S.C. § 112(f) for that claim element. Should Applicant wish to invoke Section 112(f) during prosecution of a United States patent application based on this disclosure, it will recite claim elements using the “means for” [performing a function] construct.

Different “circuits” may be described in this disclosure. These circuits or “circuitry” constitute hardware that includes various types of circuit elements, such as combinatorial logic, clocked storage devices (e.g., flip-flops, registers, latches, etc.), finite state machines, memory (e.g., random-access memory, embedded dynamic random-access memory), programmable logic arrays, and so on. Circuitry may be custom designed, or taken from standard libraries. In various implementations, circuitry can, as appropriate, include digital components, analog components, or a combination of both. Certain types of circuits may be commonly referred to as “units” (e.g., a decode unit, an arithmetic logic unit (ALU), a functional unit, a memory management unit (MMU), etc.). Such units also refer to circuits or circuitry.

The disclosed circuits/units/components and other elements illustrated in the drawings and described herein thus include hardware elements such as those described in the preceding paragraph. In many instances, the internal arrangement of hardware elements within a particular circuit may be specified by describing the function of that circuit. For example, a particular “decode unit” may be described as performing the function of “processing an opcode of an instruction and routing that instruction to one or more of a plurality of functional units,” which means that the decode unit is “configured to” perform this function. This specification of function is sufficient, to those skilled in the computer arts, to connote a set of possible structures for the circuit.

In various embodiments, as discussed in the preceding paragraph, circuits, units, and other elements may be defined by the functions or operations that they are configured to implement. The arrangement of such circuits/units/components with respect to each other and the manner in which they interact form a microarchitectural definition of the hardware that is ultimately manufactured in an integrated circuit or programmed into an FPGA to form a physical implementation of the microarchitectural definition. Thus, the microarchitectural definition is recognized by those of skill in the art as a structure from which many physical implementations may be derived, all of which fall into the broader structure described by the microarchitectural definition. That is, a skilled artisan presented with the microarchitectural definition supplied in accordance with this disclosure may, without undue experimentation and with the application of ordinary skill, implement the structure by coding the description of the circuits/units/components in a hardware description language (HDL) such as Verilog or VHDL. The HDL description is often expressed in a fashion that may appear to be functional. But to those of skill in the art in this field, this HDL description is the manner that is used to transform the structure of a circuit, unit, or component to the next level of implementational detail. Such an HDL description may take the form of behavioral code (which is typically not synthesizable), register transfer language (RTL) code (which, in contrast to behavioral code, is typically synthesizable), or structural code (e.g., a netlist specifying logic gates and their connectivity). The HDL description may subsequently be synthesized against a library of cells designed for a given integrated circuit fabrication technology, and may be modified for timing, power, and other reasons to result in a final design database that is transmitted to a foundry to generate masks and ultimately produce the integrated circuit. Some hardware circuits, or portions thereof, may also be custom-designed in a schematic editor and captured into the integrated circuit design along with synthesized circuitry. The integrated circuits may include transistors and other circuit elements (e.g., passive elements such as capacitors, resistors, inductors, etc.) and interconnect between the transistors and circuit elements. Some embodiments may implement multiple integrated circuits coupled together to implement the hardware circuits, and/or discrete elements may be used in some embodiments. Alternatively, the HDL design may be synthesized to a programmable logic array such as a field programmable gate array (FPGA) and may be implemented in the FPGA. This decoupling between the design of a group of circuits and the subsequent low-level implementation of these circuits commonly results in the scenario in which the circuit or logic designer never specifies a particular set of structures for the low-level implementation beyond a description of what the circuit is configured to do, as this process is performed at a different stage of the circuit implementation process.

The fact that many different low-level combinations of circuit elements may be used to implement the same specification of a circuit results in a large number of equivalent structures for that circuit. As noted, these low-level circuit implementations may vary according to changes in the fabrication technology, the foundry selected to manufacture the integrated circuit, the library of cells provided for a particular project, etc. In many cases, the choices made by different design tools or methodologies to produce these different implementations may be arbitrary.

Moreover, it is common for a single implementation of a particular functional specification of a circuit to include, for a given embodiment, a large number of devices (e.g., millions of transistors). Accordingly, the sheer volume of this information makes it impractical to provide a full recitation of the low-level structure used to implement a single embodiment, let alone the vast array of equivalent possible implementations. For this reason, the present disclosure describes structure of circuits using the functional shorthand commonly employed in the industry.

What is claimed is:

1. An apparatus, comprising:
a circuit block including a plurality of adjustable circuit components; and
a test circuit configured to:
determine a next vector value of a plurality of vector values using a current vector value of the plurality of vector values, wherein a given vector value of the plurality of vector values corresponds to a given combination of respective values of the plurality of adjustable circuit components;
measure an operational parameter of the circuit block using the next vector value and a plurality of local vector values associated with the next vector value to generate a plurality of results, wherein the plurality of local vector values includes a given local vector value that includes the next vector value plus an offset for one value of the plurality of adjustable circuit components;
determine a variance associated with the next vector value using the plurality of results for the next vector value;
perform a comparison of a running variance to a threshold value, wherein the running variance is based on corresponding variances associated with at least two sequential vector values of the plurality of vector values; and
select a final vector value of the plurality of vector values using a result of the comparison.

2. The apparatus of claim 1, wherein the circuit block is configured to store the final vector value.

3. The apparatus of claim 1, wherein the test circuit is further configured to determine the next vector value according to a Markov Chain Monte Carlo algorithm.

4. The apparatus of claim 1, wherein to determine the variance, the test circuit is further configured to determine respective variances of histograms for the operational parameter measured using the plurality of local vectors values.

5. The apparatus of claim 1, wherein the plurality of adjustable circuit components includes at least on transistor.

6. The apparatus of claim 1, wherein the plurality of adjustable circuit components includes at least one resistor.

7. A method, comprising:
determining, by a test circuit, a next vector value of a plurality of vector values using a current vector value of the plurality of vector values, wherein a given vector value of the plurality of vector values corresponds to a given combination of respective values for a plurality of adjustable circuit components in a circuit block;
measuring, by the test circuit, an operational parameter of the circuit block using the next vector value and a plurality of local vector values associated with the next vector value to generate a plurality of results, wherein the plurality of local vector values includes a given local vector value that includes the next vector value plus an offset for at least one value associated with the plurality of adjustable circuit components;
determining, by the test circuit, a variance associated with the next vector value using the plurality of results for the next vector value;
performing, by the test circuit, a comparison of a running variance to a threshold value, wherein the running variance is based on corresponding variances associated with at least two sequential vector values of the plurality of vector values; and
selecting, by the test circuit, a final vector value of the plurality of vector values using a result of the comparison.

8. The method of claim 7, further comprising storing, by the circuit block, the final vector value.

9. The method of claim 7, further comprising determining, by the test circuit, the next vector value according to a Markov Chain Monte Carlo algorithm.

10. The method of claim 7, wherein the test circuit and the circuit block are included on a common integrated circuit.

11. The method of claim 7, wherein determining the variance includes determining respective variances of histograms for the operational parameter measured at the plurality of local vector values.

12. The method of claim 11, further comprising determining the running variance using the respective variances of the histograms for the operational parameter.

13. The method of claim 7, wherein the plurality of adjustable circuit components includes at least one capacitor.

14. A system, comprising:
a first device configured, in response to a test mode, to transmit a test data signal via a communication link, wherein the test data signal encodes a plurality of test data symbols;
a second device including a receiver circuit that includes a plurality of adjustable circuit components, wherein the receiver circuit is configured to:
receive the test data signal via the communication link; and
sample the test data signal to decode the plurality of test data symbols; and
a test circuit configured to:
determine a next vector value of a plurality of vector values using a current vector value of the plurality of vector values, wherein a given vector value of the plurality of vector values corresponds to a given combination of respective values for the plurality of adjustable circuit components;
measure an operational parameter associated with the receiver circuit using the next vector value and a plurality of local vector values associated with the next vector value to generate a plurality of results, wherein the plurality of local vector values includes a given local vector value that includes the next vector value plus an offset for at least one value associated with the plurality of adjustable circuit components;
determine a variance associated with the next vector value using the plurality of results for the next vector value;
perform a comparison of a running variance to a threshold value, wherein the running variance is based on corresponding variances associated with at least two sequential vector values of the plurality of vector values; and
select a final vector value of the plurality of vector values using a result of the comparison.

15. The system of claim 14, wherein the communication link includes a serial-deserialization link, and wherein the operational parameter associated with the receiver circuit corresponds to an eye opening of the serial-deserialization link.

16. The system of claim 14, wherein the test circuit is further configured to determine the next vector value using respective probabilities of a subset of vector values of the plurality of vectors values.

17. The system of claim 14, wherein the plurality of adjustable circuit components includes at least one capacitor.

18. The system of claim 14, wherein the receiver circuit is further configured to:
store the final vector value; and
receive and decode, during non-test mode operation and using the final vector value, an operational data signal.

19. The system of claim 14, wherein the test circuit is included in the second device.

20. The system of claim 14, wherein the test circuit is external to the second device.
